(19) United States
(12) Patent Application Publication
(10) Pub. No.: US 2020/0390003 A1
(43) Pub. Date: Dec. 10, 2020

(54) HEAT SINK

(71) Applicant: Furukawa Electric Co., Ltd., Tokyo (JP)

(72) Inventors: Kenya KAWABATA, Tokyo (JP); Yoshikatsu INAGAKI, Tokyo (JP)

(73) Assignee: Furukawa Electric Co., Ltd., Tokyo (JP)

(21) Appl. No.: 17/002,602

(22) Filed: Aug. 25, 2020

Related U.S. Application Data
(63) Continuation of application No. PCT/JP2019/008030, filed on Mar. 1, 2019.

(30) Foreign Application Priority Data
Mar. 1, 2018 (JP) 2018-036148

(51) Int. Cl. H05K 7/20

(52) U.S. Cl. CPC H05K 7/20163; H05K 7/20409

(57) ABSTRACT

Example embodiments may provide a heat sink that cools a heating element. The heat sink may include a heat receiving unit thermally connected to a heating element, a plurality of heat pipes thermally connected to the heat receiving unit at a predetermined part, and a heat dissipation unit thermally connected to another part different from the predetermined part of the plurality of heat pipes.

### CROSS REFERENCE TO RELATED APPLICATIONS

The present application is a continuation application of International Patent Application No. PCT/JP2019/008030 filed on Mar. 1, 2019, which claims the benefit of Japanese Patent Application No. 2018-036148, filed on Mar. 1, 2018. The contents of these applications are incorporated herein by reference in their entirety.

### BACKGROUND

### Technical Field

The present disclosure relates to a heat sink that cools a heating element, and more particularly, to a heat pipe type heat sink.

### Background

As electronic apparatuses are provided with increasingly higher functions, heating elements such as electronic parts are mounted in a high density inside the electronic apparatuses. A heat sink provided with heat pipes (heat pipe type heat sink) may be used as a unit configured to cool heating elements such as electronic parts. As the above-described heat sink, for example, a heat pipe type heat sink is proposed, in which many plate-shaped heat dissipation fins are provided in such a way as to protrude in a radius direction on outer circumferential surfaces of heat pipes provided in plurality (Japanese Patent Application Laid-Open No. 2003-110072).

According to Japanese Patent Application Laid-Open No. 2003-110072, the plurality of heat pipes are disposed in parallel along a flowing direction of cooling air supplied from a fan for forced air cooling. That is, the plurality of heat pipes include heat pipes, a condensation unit of which is disposed on a windward side of the cooling air and heat pipes, a condensation unit of which is disposed on a leeward side of the cooling air.

On the other hand, heat pipes, an evaporation unit of which is attached at a position close to a heating element, which is an object to be cooled, have a large incoming heat amount from the heating element and require a greater heat transport amount than heat pipes, an evaporation unit of which is attached at a position far from the heating element, and so cooling capability of the heat pipes needs to be improved accordingly. When cooling capability of the heat pipes, the evaporation unit of which is attached at the position close to the heating element is not sufficient, the heat pipes cannot take heat from the heating element sufficiently, and as a result, the temperature of the heating element rises. Therefore, the heat pipes, the evaporation unit of which is attached at the position close to the heating element are required to have a characteristic with high cooling capability. When each heat pipe has predetermined thermal resistance, it is possible to improve the cooling capability of the heat pipe, the evaporation unit of which is attached at the position close to the heating element, by supplying low temperature cooling air to the condensation unit of the heat pipe, the evaporation unit of which is attached at the position close to the heating element and obtaining a temperature difference between heat dissipation fins thermally connected to the condensation unit and the cooling air. Note that “cooling capability of the heat pipe” means capability of lowering the temperature of the evaporation unit of the heat transporting (that is, operating) heat pipes and “improving the cooling capability of the heat pipe” means that the temperature of the evaporation unit of the heat pipes carrying out heat transportation further lowers.

However, according to Japanese Patent Application Laid-Open No. 2003-110072, the plurality of heat pipes are disposed in parallel so that the longitudinal directions of the heat pipes become substantially parallel, nothing more than one end of any heat pipe being thermally connected to a heating portion to form the evaporation unit and the other end being thermally connected to the heat dissipation fins to form the condensation unit. Therefore, there may be cases where cooling capability of heat pipes having large incoming heat amounts from a heating element cannot be improved, and so there remains room for improvement in the heat dissipation characteristic of the heat sink.

### SUMMARY

The present disclosure is related to providing a heat sink capable of showing excellent cooling performance on an object to be cooled by improving cooling capability of heat pipes having relatively large incoming heat amounts from a heating element, which is an object to be cooled, among a plurality of heat pipes.

According to one aspect of the present disclosure, a heat sink includes a heat receiving unit thermally connected to a heating element, a plurality of heat pipes thermally connected to the heat receiving unit at a predetermined part and a heat dissipation unit thermally connected to another part different from the predetermined part of the plurality of heat pipes, in which among the plurality of heat pipes, the other part of a first heat pipe where at least part of the predetermined part or a virtual straight line extending along an extending direction of the predetermined part from an end portion of the predetermined part overlaps an area of the heating element having a high heat generation density in a plan view is provided closer to a windward side of cooling air than the other part of a second heat pipe where the predetermined part or a virtual straight line extending along an extending direction of the predetermined part from an end portion of the predetermined part does not overlap the area of the heating element having a high heat generation density in a plan view.

According to the above-described aspect of the present disclosure, the heat pipe receives heat from the heating element in the predetermined part, and so the predetermined part constitutes an evaporation unit, and emits heat from the heating element in the other part to the heat dissipation unit, and so the other part constitutes a condensation unit. Note that the “plan view” in the present specification means a state visually recognized from a direction orthogonal to a heat transporting direction of the heat pipe and from a direction orthogonal to an arrangement direction of the predetermined part of the heat pipe.

Another aspect of the present disclosure is the heat sink including an intersection where the first heat pipe and the second heat pipe cross each other in a plan view.

A further aspect of the present disclosure is the heat sink including an intersection where an intermediate portion positioned between the predetermined part and the other part of the first heat pipe and an intermediate portion positioned between the predetermined part and the other part of the second heat pipe cross each other in a plan view.

A further aspect of the present disclosure is the heat sink in which in the intersection, the first heat pipe and/or the second heat pipe are/is processed into a flat shape.

A further aspect of the present disclosure is the heat sink in which the predetermined part is one end portion in a longitudinal direction of the heat pipe and the other part is another end portion in the longitudinal direction of the heat pipe.

A further aspect of the present disclosure is the heat sink in which the predetermined part is a central part in the longitudinal direction of the heat pipe and the other part is one end portion and the other end portion in the longitudinal direction of the heat pipe.

In accordance with the aspect of the present disclosure, among the plurality of heat pipes, the condensation unit of the first heat pipe where the virtual straight line extending along the extending direction of the evaporation unit from at least part of the evaporation unit or the end portion of the evaporation unit overlaps the area of the heating element having a high heat generation density in a plan view is provided closer to the windward side of the cooling air than the condensation unit of the second heat pipe where the virtual straight line extending along the extending direction of the evaporation unit from the evaporation unit or the end portion of the evaporation unit does not overlap the area of the heating element having a high heat generation density in a plan view, and therefore the temperature of the cooling air supplied to the first heat pipe is lower than the temperature of the cooling air supplied to the second heat pipe. Therefore, the heat exchange amount of the first heat pipe is improved more than the heat exchange amount of the second heat pipe. From above, heat exchange of the first heat pipe having a relatively large incoming heat amount from the heating element among the plurality of heat pipes is promoted and the cooling capability is improved, and as a result, it is possible to obtain a heat sink capable of showing excellent cooling performance on an object to be cooled.

According to the other aspect of the present disclosure, since the heat sink is provided with the intersection at which the first heat pipe and the second heat pipe cross each other in a plan view, even when the heating element, which is an object to be cooled, is thermally connected to the central part of the heat receiving unit, the condensation unit of the first heat pipe can be disposed closer to the windward side of the cooling air than the condensation unit of the second heat pipe.

According to the further aspect of the present disclosure, the first heat pipe and/or the second heat pipe are/is processed into a flat shape at the intersection between the first heat pipe and the second heat pipe, and therefore the thickness of the above-described intersection is reduced and the heat sink can be made more compact. Therefore, the heat sink can be installed even in a small space.

### BRIEF DESCRIPTION OF THE DRAWINGS

FIG. 1 is an explanatory diagram in a plan view of a heat sink according to a first embodiment of the present disclosure;

FIG. 2 is an explanatory diagram in a plan view of a heat sink according to a second embodiment of the present disclosure; and

FIG. 3 is an explanatory diagram in a plan view of a heat sink according to a third embodiment of the present disclosure.

### DETAILED DESCRIPTION

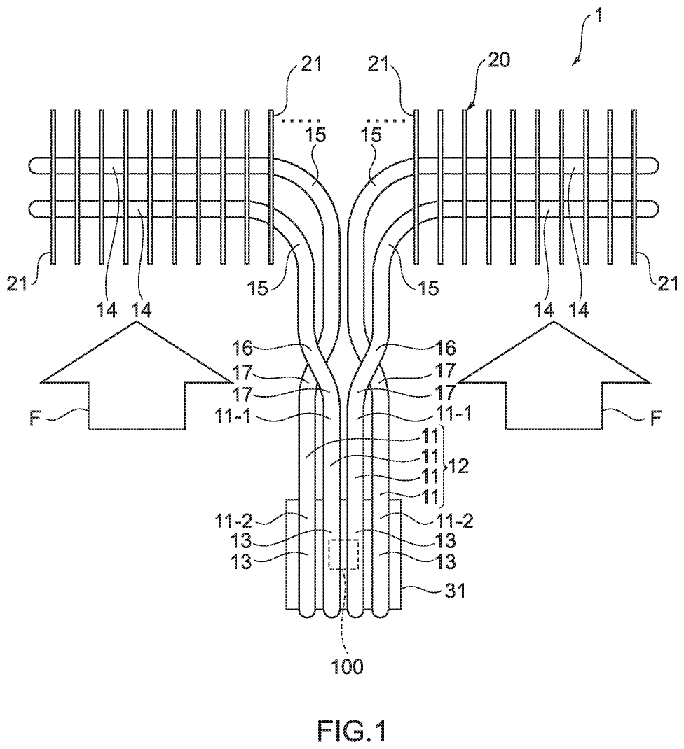

Hereinafter, a heat sink according to a first embodiment of the present disclosure will be described with reference to the accompanying drawings. As shown in FIG. 1, a heat sink 1 according to the first embodiment is provided with a heat receiving plate 31 thermally connected to a heating element 100, which is an object to be cooled and a plurality of (four in FIG. 1) heat pipes 11 thermally connected to the heat receiving plate 31. All the plurality of heat pipes 11 are thermally connected to a common heat dissipation unit 20 of the heat sink 1.

The heat pipe 11 is a heat transporting member with a working fluid sealed in a container made of an elongated tube member. The container is a hermetically sealed container and an inside of the container is decompressed. A longitudinal direction of the heat pipe 11 corresponds to a heat transporting direction of the heat pipe 11.

The plurality of heat pipes 11 are disposed in parallel in a direction substantially orthogonal to the longitudinal direction of the heat pipes 11, forming a heat pipe group 12. All the plurality of heat pipes 11 are disposed so as to laterally face other adjacent heat pipes 11. One end portions 13 of all the plurality of heat pipes 11 are thermally connected to the heating element 100, and the one end portion of the heat pipe group 12 is thereby thermally connected to the heating element 100. In the heat sink 1, the one end portions 13 of the heat pipes 11 are indirectly contacted with a surface of the heating element 100 via the heat receiving plate 31 having a plate shape to thereby thermally connect the one end portions 13 of the heat pipes 11 to the heating element 100. Therefore, the one end portions 13 of the heat pipes 11 are thermally connected to the heat receiving plate 31. The one end portions 13 of the heat pipes 11 are thermally connected to the heat receiving plate 31 to thereby function as an evaporation unit. In the heat sink 1, the one end portions 13 of the heat pipes 11 extend along the plane direction of the heat receiving plate 31 in the longitudinal direction.

Among the plurality of heat pipes 11 disposed in parallel, first heat pipes 11-1 positioned at a center in parallel arrangement at the one end portion of the heat pipe group 12 are provided at positions where the one end portions 13 overlap the heating element 100 in a plan view. Therefore, the one end portions 13 of the first heat pipes 11-1 are provided at positions where the one end portions 13 overlap an area of the heating element 100, which is a hot spot and having a high heat generation density in a plan view. Note that in FIG. 1, the entire heating element 100 is assumed to be an area having a high heat generation density for convenience. The number of first heat pipes 11-1 provided at positions where the one end portions 13 overlap the heating element 100 in a plan view is not particularly limited and is assumed to be 2 in the heat sink 1. On the other hand, the one end portions 13 of second heat pipes 11-2 disposed on both sides of the first heat pipes 11-1 (that is, positions at both ends of the parallel arrangement in the one end portion of the heat pipe group 12) of the one end portion of the heat pipe group 12 are provided at positions where the second heat pipes 11-2 do not overlap the heating element 100 in a plan view. Therefore, the one end portions 13 of the second heat pipes 11-2 are provided at positions where the one end portions 13 of the second heat pipes 11-2 do not overlap an area of the heating element 100 having a high heat generation density in a plan view. The number of second heat pipes 11-2 provided at positions where the one end portions 13 of the second heat pipes 11-2 do not overlap the heating element 100 in a plan view is not particularly limited, and one of the second heat pipes 11-2 is provided at each side of the two first heat pipes 11-1 disposed in parallel in the heat sink 1.

From above, the two first heat pipes 11-1 disposed in parallel are the heat pipes 11 where incoming heat amounts from the heating element 100 are larger than incoming heat amounts of the second heat pipes 11-2 disposed on both sides of the two first heat pipes 11-1.

As shown in FIG. 1, other end portions 14 of all the plurality of heat pipes 11 are thermally connected to the heat dissipation unit 20, and the other end portion of the heat pipe group 12 is thereby thermally connected to the heat dissipation unit 20. Therefore, the other end portions 14 of the heat pipes 11 thermally connected to the heat dissipation unit 20 function as a condensation unit. Note that the heat dissipation unit 20 has a substantially rectangular parallelepiped external shape.

In the heat sink 1, bent portions 15 are formed in front of the areas of the first heat pipes 11-1 and the second heat pipes 11-2 thermally connected to the heat dissipation unit 20. Therefore, both the first heat pipes 11-1 and the second heat pipes 11-2 are substantially L-shaped in a plan view. In the heat sink 1, in correspondence with the fact that the heat pipes 11 are introduced into the heat dissipation unit 20 from the central part in a longitudinal direction of the heat dissipation unit 20, of the bent portions 15 of the first heat pipes 11-1 and the bent portions 15 of the second heat pipes 11-2, the first heat pipe 11-1 and the second heat pipe 11-2 positioned at the right side are bent rightward at introduction parts to the heat dissipation unit 20. On the other hand, the first heat pipe 11-1 and the second heat pipe 11-2 positioned at the left side are bent leftward at introduction parts to the heat dissipation unit 20. Thus, with the bent portions 15, the other end portions 14 of the first heat pipes 11-1 and the second heat pipes 11-2 extend in a direction substantially parallel to the longitudinal direction of the heat dissipation unit 20, an external shape of which is substantially rectangular parallelepiped. Of the plurality of heat pipes 11, the other end portions 14 of the first heat pipe 11-1 and the second heat pipe 11-2 positioned on the right side at the introduction parts to the heat dissipation unit 20 are disposed parallel to the direction substantially orthogonal to the longitudinal direction of the heat pipes 11. On the other hand, the other end portions 14 of the first heat pipe 11-1 and the second heat pipe 11-2 positioned on the left side at the introduction parts to the heat dissipation unit 20 are disposed parallel to the direction substantially orthogonal to the longitudinal direction of the heat pipes 11. Furthermore, one of the other end portions 14 of the heat pipe 11 is disposed so as to laterally face the other end portion 14 of the other neighboring heat pipe 11.

The heat dissipation unit 20 is provided with a plurality of heat dissipation fins 21. The heat dissipation fins 21 are thin plate-shaped members. The heat dissipation fins 21 are disposed in parallel at predetermined intervals in a direction substantially parallel to the longitudinal direction of the heat dissipation unit 20. Main surfaces of the heat dissipation fins 21 are surfaces mainly showing a heat dissipation function of the heat dissipation fins 21. The main surfaces of the respective heat dissipation fins 21 are disposed in a direction substantially orthogonal to the other end portions 14, which are linear in a plan view, of the heat pipes 11 bent rightward and the heat pipes 11 bent leftward. Therefore, the main surfaces of the heat dissipation fins 21 form a transverse direction of the heat dissipation unit 20.

The heat sink 1 is forcibly air-cooled by a blowing fan (not shown). Cooling air F derived from the blowing fan is supplied to the heat dissipation unit 20 along the transverse direction of the heat dissipation unit 20 to cool the heat dissipation fins 21.

As shown in FIG. 1, the heat sink 1 is provided with intersections 16 where the first heat pipes 11-1 and the second heat pipes 11-2 cross each other in a plan view. Each of the first heat pipes 11-1 forms the intersection 16 together with the neighboring one of the plurality of (two in FIG. 1) second heat pipes 11-2. Here, each of the first heat pipes 11-1 forms the intersection 16 together with the second heat pipe 11-2, the one end portion 13 of which is adjacent to the outer surface of the heat pipe group 12 arranged in parallel. The first heat pipe 11-1, the one end portion 13 of which is positioned at the center of the heat pipe group 12 arranged in parallel, forms the intersection 16 together with the second heat pipe 11-2, the one end portion 13 of which is adjacent to the outer surface of the heat pipe group 12 arranged in parallel, so that the other end portions 14 of the first heat pipes 11-1 are positioned closer to the windward side of the cooling air F than the other end portions 14 of the second heat pipes 11-2, the one end portions 13 of which are positioned on the outer surface of the heat pipe group 12 arranged in parallel.

From above, in the heat sink 1, both of the one end portions 13 of the second heat pipes 11-2 disposed on both sides of the first heat pipes 11-1 form the intersections 16 together with the first heat pipes 11-1 adjacent to the inner surface of the heat pipe group 12 arranged in parallel.

By the first heat pipes 11-1 and the second heat pipes 11-2 crossing each other in the direction from the one end portions 13 to the other end portions 14, from the center of the heat pipe group 12 arranged in parallel toward the end portion of the outer surface, and from the end portion of the outer surface of the heat pipe group 12 arranged in parallel toward the center respectively at the intersection 16, the other end portions 14 of the first heat pipes 11-1 are positioned closer to the windward side of the cooling air F than the other end portions 14 of the second heat pipes 11-2. Therefore, the other end portions 14 of the first heat pipes 11-1 are positioned closer to the windward side of the cooling air F than any of the other end portions 14 of the second heat pipes 11-2.

In the heat sink 1, in each of the first heat pipes 11-1, central parts 17 positioned between the one end portions 13 and the other end portions 14 of the first heat pipes 11-1, and central parts 17 positioned between the one end portions 13 and the other end portions 14 of the second heat pipes 11-2 cross each other to form the intersections 16 in a plan view.

At the intersections 16 between the first heat pipes 11-1 and the second heat pipes 11-2, the first heat pipes 11-1 and/or the second heat pipes 11-2 may be processed into a flat shape as required. When the first heat pipes 11-1 and/or the second heat pipes 11-2 are processed into a flat shape at the intersections 16, the thickness of the intersection 16 is reduced, making it possible to make the heat sink 1 more compact, and as a result, install the heat sink 1 even in a small space, especially in a space, which is narrow in the thickness direction.

The material of the heat dissipation fins 21 is not particularly limited, and examples of the material may include metals such as copper, copper alloy, aluminum, aluminum alloy. The material of the containers of the heat pipes 11 is not particularly limited, and examples of the material may include metals such as copper, copper alloy, aluminum, aluminum alloy, stainless steel. The working fluid to be sealed in the heat pipes 11 can be selected as appropriate depending on the material of the containers, and examples of the material may include water, alternative chlorofluorocarbon, perfluorocarbon, cyclopentane.

Thereafter, a mechanism of the cooling function of the heat sink 1 will be described. First, heat is transmitted from the heating element 100 to the one end portions 13 of the heat pipes 11 via the heat receiving plate 31. When heat is transmitted from the heating element 100 to the one end portions 13 of the heat pipes 11, the heat transmitted by heat transporting action of the heat pipes 11 is transported along the longitudinal direction of the heat pipes 11 from the one end portions 13, which is an evaporation unit, to the other end portions 14, which is a condensation unit. At this time, the plurality of (two in FIG. 1) first heat pipes 11-1 having large incoming heat amounts from the heating element 100 contribute to more heat transportation than the second heat pipes 11-2. Heat transported to the other end portions 14 of the heat pipes 11 is transmitted from the other end portions 14 of the heat pipes 11 to the heat dissipation unit 20 and the heat transmitted to the heat dissipation unit 20 is emitted from the heat dissipation unit 20 to the outside. The heat of the heating element 100 is emitted from the heat dissipation unit 20 to the outside, and the heating element 100 is thereby cooled.

In the heat sink 1, since the condensation unit (other end portions 14) of the first heat pipes 11-1 having a larger incoming heat amount from the heating element 100 than the second heat pipes 11-2 is provided closer to the windward side of the cooling air F than the condensation unit (other end portions 14) of the second heat pipes 11-2, the temperature of the cooling air F supplied to the condensation unit of the first heat pipes 11-1 is lower than the temperature of the cooling air F supplied to the condensation unit of the second heat pipes 11-2. That is, a temperature difference between the heat dissipation fins 21 thermally connected to the condensation unit and the cooling air is greater in the first heat pipes 11-1 than in the second heat pipes 11-2. Therefore, the heat exchange amount of any one of the first heat pipes 11-1 is improved compared to the heat exchange amount of the second heat pipes 11-2. From above, among the plurality of heat pipes 11, the cooling air F having a low temperature is supplied to the condensation unit of the first heat pipes 11-1 having a relatively large incoming heat amount from the heating element 100, and so a temperature difference between the evaporation unit and the condensation unit of the first heat pipes 11-1 is greater than a temperature difference between the evaporation unit and the condensation unit of the second heat pipes 11-2, and heat exchange of the first heat pipes 11-1 is thereby promoted, cooling capability of the first heat pipes 11-1 improves, and as a result, the heat sink 1 can show excellent cooling performance on an object to be cooled.

Note that even when the condensation unit of the first heat pipes 11-1 is provided closer to the windward side of the cooling air F than the condensation unit of the second heat pipes 11-2, the heat sink 1 is configured to have a desired maximum heat transport amount.

Thereafter, a heat sink according to a second embodiment of the present disclosure will be described with reference to the accompanying drawings. Note that the same components as the components of the heat sink according to the first embodiment will be described using the same reference numerals.

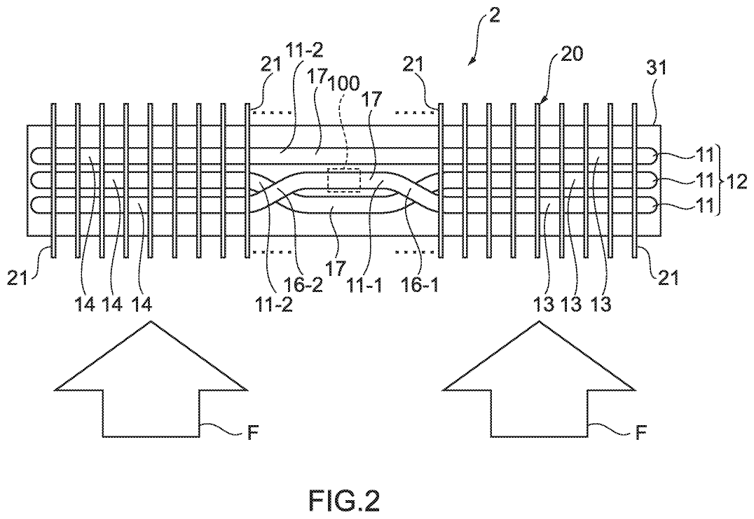

In the heat sink 1 according to the first embodiment, the one end portions 13 of the heat pipes 11 function as the evaporation unit, and the other end portions 14 function as the condensation unit, and the one end portions 13 are thermally connected to the heat receiving plate 31. Instead of this, as shown in FIG. 2, in a heat sink 2 according to the second embodiment, central parts 17 of the heat pipes 11 function as an evaporation unit, the one end portions 13 and the other end portions 14 function as a condensation unit, and the heat receiving plate 31 extends from the one end portions 13 to the other end portions 14 of the heat pipes 11. The heating element 100 is thermally connected to substantially a center of the heat receiving plate 31.

A plurality of (three in FIG. 2) heat pipes 11 are disposed in parallel in a direction substantially orthogonal to the longitudinal direction of the heat pipes 11 to form the heat pipe group 12. In correspondence with the fact that the heating element 100 is thermally connected to substantially the center of the heat receiving plate 31, the heating element 100 is thermally connected to the central parts 17 of the heat pipes 11. Thus, the central parts 17 of the heat pipes 11 function as the evaporation unit.

Among the plurality of heat pipes 11 disposed in parallel, the central part 17 of the first heat pipe 11-1 (one in FIG. 2) positioned at the center of the parallel arrangement at the central part in the longitudinal direction of the heat pipe group 12 is provided at a position where the first heat pipe 11-1 overlaps the heating element 100 in a plan view. On the other hand, central parts 17 of second heat pipes 11-2 disposed on both sides of the heat pipe group 12 (that is, positions at both ends of the parallel arrangement in the central part in the longitudinal direction of the heat pipe group 12) are provided at positions where the second heat pipes 11-2 do not overlap the heating element 100 in a plan view.

In the heat sink 2, cooling air F is mainly supplied to the one end portions 13 and the other end portions 14 of the heat pipes 11. Therefore, the one end portions 13 and the other end portions 14 of the heat pipes 11 function as a condensation unit.

In the heat sink 2, the plurality of heat dissipation fins 21 are disposed upright on the heat receiving plate 31 to thereby form the heat dissipation unit 20. The heat dissipation fins 21 are disposed in parallel at predetermined intervals on the heat receiving plate 31. The heat dissipation fins 21 are disposed in parallel from a part corresponding to the one end portions 13 to a part corresponding to the other end portions 14 of the heat pipes 11.

In the heat sink 2, in correspondence with the fact that the central part 17 of the heat pipes 11 functions as the evaporation unit, and the one end portions 13 and the other end portions 14 function as the condensation unit, an intersection 16-1 that crosses one of the plurality of (two in FIG. 2) second heat pipes 11-2 in a plan view is provided between the central part 17 of the first heat pipe 11-1 and the one end portions 13. Furthermore, an intersection 16-2 that crosses the second heat pipes 11-2 forming the intersection 16-1 in a plan view is also provided between the central part 17 of the first heat pipe 11-1 and the other end portions 14. The first heat pipe 11-1 forms the intersections 16-1 and 16-2, together with one of the plurality of second heat pipes 11-2 that is positioned on a most windward side of the cooling air F. On the other hand, the first heat pipe 11-1 forms no intersection with the one of the plurality of second heat pipes 11-2 positioned on a most leeward side of the cooling air F.

By the first heat pipe 11-1 and one of the plurality of second heat pipes 11-2 crossing each other in the direction from the central part 17 toward the one end portions 13, from the center of the heat pipe group 12 arranged in parallel toward the windward end portion, and from the windward end portion of the heat pipe group 12 arranged in parallel toward the center respectively at the intersection 16-1, the one end portion 13 of the first heat pipe 11-1 is positioned closer to the windward side of the cooling air F than the one end portions 13 of the second heat pipes 11-2. Therefore, the one end portion 13 of the first heat pipe 11-1 is positioned closer to the windward side of the cooling air F than the one end portions 13 of the second heat pipes 11-2.

By the first heat pipe 11-1 and one of the plurality of second heat pipes 11-2 crossing each other in the direction from the central part 17 toward the other end portions 14, from the center of the heat pipe group 12 arranged in parallel toward the windward end portion, and from the windward end portion of the heat pipe group 12 arranged in parallel toward the center respectively at the intersection 16-2, the other end portion 14 of the first heat pipe 11-1 is positioned closer to the windward side of the cooling air F than the other end portions 14 of the second heat pipes 11-2. Therefore, the other end portion 14 of the first heat pipe 11-1 is positioned closer to the windward side of the cooling air F than the other end portions 14 of the second heat pipes 11-2.

In the heat sink 2, since the temperature of the cooling air F supplied to the condensation unit of the first heat pipe 11-1 is lower than the temperature of the cooling air F supplied to the condensation unit of the second heat pipes 11-2, a temperature difference between the heat dissipation fins 21 thermally connected to the condensation unit and the cooling air is larger in the first heat pipe 11-1 than in the second heat pipes 11-2. Therefore, a heat exchange amount of the first heat pipe 11-1 is improved compared to a heat exchange amount of the second heat pipes 11-2. From above, among the plurality of heat pipes 11, the cooling air F having a low temperature is supplied to the condensation unit of the first heat pipe 11-1 having a relatively large incoming heat amount from the heating element, and so a temperature difference between the evaporation unit and the condensation unit of the first heat pipe 11-1 is larger than a temperature difference between the evaporation unit and the condensation unit of the second heat pipes 11-2, heat exchange of the first heat pipe 11-1 is promoted, cooling capability of the first heat pipe 11-1 improves, and as a result, the heat sink 2 can also show excellent cooling performance on the heating element 100, which is an object to be cooled.

Thereafter, a heat sink according to a third embodiment of the present disclosure will be described with reference to the accompanying drawings. Note that the same components as the components of the heat sinks according to the first and second embodiments will be described using the same reference numerals.

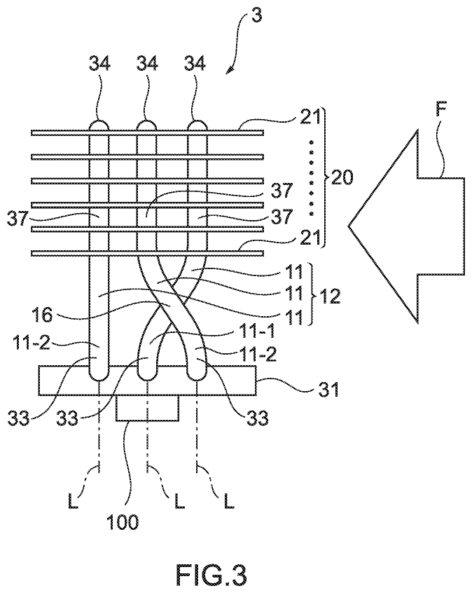

In the heat sinks 1 and 2 according to the first and second embodiments, the longitudinal direction of the heat pipes 11 extends along the plane direction of the heat receiving plate 31 to which the heating element 100 is thermally connected, but instead of this, as shown in FIG. 3, in a heat sink 3 according to the third embodiment, a plurality of heat pipes 11 are provided upright on the heat receiving plate 31. That is, the heat sink 3 is a tower-type heat sink. In the heat sink 3, the heat pipes 11 extend in a direction perpendicular to the plane part of the heat receiving plate 31. The heating element 100 is thermally connected to substantially the center of the heat receiving plate 31.

In the heat sink 3, the plurality of (three in FIG. 3) heat pipes 11 are disposed in parallel in a direction substantially orthogonal to the longitudinal direction (upright direction) of the heat pipes 11 to form the heat pipe group 12. In correspondence with the fact that the heating element 100 is thermally connected to the heat receiving plate 31, the heating element 100 is thermally connected to heat receiving unit side bases 33 of the heat pipes 11. Therefore, the heat receiving unit side bases 33 of the heat pipes 11 function as evaporation unit.

Among the plurality of heat pipes 11 disposed in parallel, the first heat pipe 11-1 (one in FIG. 3) positioned at the center in parallel arrangement on the heat receiving unit side base of the heat pipe group 12 is provided at a position where a virtual straight line L extending along the extending direction of the heat receiving unit side base 33 from the end portion of the heat receiving unit side base 33 overlaps the heating element 100 in a plan view. Therefore, the heat receiving unit side base 33 of the first heat pipe 11-1 is provided at a position where the virtual straight line L overlaps an area having a high heat generation density of the heating element 100 in a plan view. Note that in FIG. 3, the entire heating element 100 is assumed to be the area having a high heat generation density for convenience. On the other hand, the second heat pipes 11-2 disposed on both sides of the heat pipe group 12 (that is, positions at both ends in parallel arrangement on the heat receiving unit side base of the heat pipe group 12) are provided at positions where the virtual straight lines L extending along the extending direction of the heat receiving unit side bases 33 from the end portions of the heat receiving unit side bases 33 do not overlap the heating element 100 in a plan view. Therefore, the heat receiving unit side bases 33 of the second heat pipes 11-2 are provided at positions where the virtual straight lines L do not overlap the area having a high heat generation density of the heating element 100 in a plan view.

In the heat sink 3, the heat dissipation fins 21 are attached to the heat pipes 11 to thereby form the heat dissipation unit 20. The parts where the heat dissipation fins 21 are attached function as the condensation unit of the heat pipes 11. The positions where the heat dissipation fins 21 are attached are not particularly limited, but in the heat sink 3, the plurality of heat dissipation fins 21 are attached from distal end portions 34 of the heat pipes 11 to central parts 37 in the longitudinal direction. The heat dissipation fins 21 are disposed in parallel, substantially parallel to the extending direction of the heat pipes 11 at predetermined intervals. Main surfaces of the heat dissipation fins 21 extend substantially parallel to the plane part of the heat receiving plate 31. The cooling air F is mainly supplied to the central parts 37 in the longitudinal direction from the distal end portion 34 of the heat pipes 11.

In the heat sink 3, in correspondence with the fact that the heat receiving unit side bases 33 of the heat pipes 11 function as the evaporation unit and the distal end portions 34 to the central parts 37 in the longitudinal direction function as the condensation unit, the intersection 16 is provided between the central part 37 in the longitudinal direction and the heat receiving unit side base 33 (intermediate portion) of the first heat pipe 11-1 where the first heat pipe 11-1 and one of the plurality of (two in FIG. 3) second heat pipes 11-2 cross each other in a plan view. The first heat pipe 11-1 forms the intersection 16 together with the second heat pipe 11-2 positioned on a most windward side of the cooling air F among the plurality of second heat pipes 11-2.

By the first heat pipe 11-1 and one of the plurality of second heat pipes 11-2 crossing each other in a direction from the heat receiving unit side bases 33 to the distal end portions 34, from the center of the heat pipe group 12 arranged in parallel toward the windward end portion, and from the windward end portion of the heat pipe group 12 arranged in parallel toward the center respectively at the intersection 16, the distal end portion 34 of the first heat pipe 11-1 and the central part 37 in the longitudinal direction are positioned closer to the windward side of the cooling air F than the distal end portions 34 of the second heat pipes 11-2 and the central parts 37 in the longitudinal direction. Therefore, the distal end portion 34 of the first heat pipe 11-1 and the central part 37 in the longitudinal direction are positioned doser to the windward side of the cooling air F than the distal end portion 34 of any one of the second heat pipes 11-2 and the central part 37 in the longitudinal direction.

In the heat sink 3, which is a tower-type heat sink, the temperature of the cooling air F supplied to the condensation unit of the first heat pipe 11-1 is lower than the temperature of the cooling air F supplied to the condensation unit of the second heat pipes 11-2, and so a temperature difference between the heat dissipation fins 21 thermally connected to the condensation unit and the cooling air is larger in the first heat pipe 11-1 than in the second heat pipes 11-2. Therefore, the heat exchange amount of the first heat pipe 11-1 is improved compared to the heat exchange amount of the second heat pipes 11-2. From above, among the plurality of heat pipes 11, the cooling air F having a lower temperature is supplied to the condensation unit of the first heat pipe 11-1 having a relatively large incoming heat amount from the heating element, the temperature difference between the evaporation unit and the condensation unit of the first heat pipe 11-1 is larger than the temperature difference between the evaporation unit and the condensation unit of the second heat pipes 11-2, heat exchange of the first heat pipe 11-1 is promoted, cooling capability of the first heat pipe 11-1 improves, and as a result, the heat sink 3 can show excellent cooling performance on the heating element 100, which is an object to be cooled.

Thereafter, other embodiments of a heat sink of the present disclosure will be described. Although the number of heat pipes forming the heat pipe group is 3 or 4 in the above-described embodiments, the number of heat pipes in the heat pipe group needs only to be plural, and can be selected as appropriate in accordance with the heat generation amount or the like of the heating element, and can be 2 or 5 or more. Although the number of first heat pipes is 1 or 2 in the above-described embodiments, the number of first heat pipes is not particularly limited and may be 3 or more. Although the number of second heat pipes is 2 in the above-described embodiments, the number of second heat pipes is not particularly limited and may be 1 or 3 or more.

In the heat sink according to the first embodiment, the respective central parts of the first heat pipes cross the central parts of the second heat pipes in a plan view to form the intersections. Instead of this, the one end portions of the respective first heat pipes may cross the one end portions of the second heat pipes in a plan view to form the intersections or the other end portions of the respective first heat pipes may cross the other end portions of the second heat pipes in a plan view to form the intersections. Furthermore, in the above-described embodiments, in correspondence with the fact that the central part of the heating element has a high heat generation density, the first heat pipes are disposed so that the evaporation unit of the first heat pipe or the virtual line extending from the evaporation unit overlaps the central part of the heating element in a plan view. However, the evaporation unit of the first heat pipe or the virtual line extending from the evaporation unit is disposed at a position where the evaporation unit or the virtual line overlaps the area of the heating element having a high heat generation density in a plan view. Therefore, in the case where the area of the heating element having a high heat generation density is other than the central part, the first heat pipe is disposed so that the evaporation unit of the first heat pipe or the virtual line extending from the evaporation unit overlaps at least the area other than the central part in a plan view.

The heat sink of the present disclosure can be used in a wide range of fields, and can improve cooling capability of heat pipes having a relatively high incoming heat amount from a heating element, and thereby exhibits a high utility value in the field of cooling electronic parts mounted on, for example, a server, a desktop-type personal computer or a data center.

What is claimed is:

1. A heat sink comprising:
a heat receiving unit thermally connected to a heating element;
a plurality of heat pipes thermally connected to the heat receiving unit at a predetermined part; and
a heat dissipation unit thermally connected to another part different from the predetermined part of the plurality of heat pipes, wherein
among the plurality of heat pipes, the other part of a first heat pipe where at least part of the predetermined part or a virtual straight line extending along an extending direction of the predetermined part from an end portion of the predetermined part overlaps an area of the heating element having a high heat generation density in a plan view is provided closer to a windward side of cooling air than the other part of a second heat pipe where the predetermined part or a virtual straight line extending along an extending direction of the predetermined part from an end portion of the predetermined part does not overlap the area of the heating element having a high heat generation density in a plan view.

2. The heat sink according to claim 1, further comprising an intersection where the first heat pipe and the second heat pipe cross each other in a plan view.

3. The heat sink according to claim 1, further comprising:
an intersection where an intermediate portion positioned between the predetermined part and the other part of the first heat pipe and an intermediate portion positioned between the predetermined part and the other part of the second heat pipe cross each other in a plan view.

4. The heat sink according to claim 2, further comprising:
the intersection where an intermediate portion positioned between the predetermined part and the other part of the first heat pipe and an intermediate portion positioned between the predetermined part and the other part of the second heat pipe cross each other in the plan view.

5. The heat sink according to claim 2, wherein in the intersection, the first heat pipe and/or the second heat pipe are/is processed into a flat shape.

6. The heat sink according to claim 3, wherein in the intersection, the first heat pipe and/or the second heat pipe are/is processed into a flat shape.

7. The heat sink according to claim 4, wherein in the intersection, the first heat pipe and/or the second heat pipe are/is processed into a flat shape.

8. The heat sink according to claim 1, wherein the predetermined part is one end portion in a longitudinal direction of the heat pipe and the other part is another end portion in the longitudinal direction of the heat pipe.

9. The heat sink according to claim 2, wherein the predetermined part is one end portion in a longitudinal direction of the heat pipe and the other part is another end portion in the longitudinal direction of the heat pipe.

10. The heat sink according to claim 3, wherein the predetermined part is one end portion in a longitudinal direction of the heat pipe and the other part is another end portion in the longitudinal direction of the heat pipe.

11. The heat sink according to claim 4, wherein the predetermined part is one end portion in a longitudinal direction of the heat pipe and the other part is another end portion in the longitudinal direction of the heat pipe.

12. The heat sink according to claim 5, wherein the predetermined part is one end portion in a longitudinal direction of the heat pipe and the other part is another end portion in the longitudinal direction of the heat pipe.

13. The heat sink according to claim 6, wherein the predetermined part is one end portion in a longitudinal direction of the heat pipe and the other part is another end portion in the longitudinal direction of the heat pipe.

14. The heat sink according to claim 7, wherein the predetermined part is one end portion in a longitudinal direction of the heat pipe and the other part is another end portion in the longitudinal direction of the heat pipe.

15. The heat sink according to claim 1, wherein the predetermined part is a central part in the longitudinal direction of the heat pipe and the other part is one end portion and the other end portion in the longitudinal direction of the heat pipe.

16. The heat sink according to claim 2, wherein the predetermined part is a central part in the longitudinal direction of the heat pipe and the other part is one end portion and the other end portion in the longitudinal direction of the heat pipe.

17. The heat sink according to claim 3, wherein the predetermined part is a central part in the longitudinal direction of the heat pipe and the other part is one end portion and the other end portion in the longitudinal direction of the heat pipe.

18. The heat sink according to claim 4, wherein the predetermined part is a central part in the longitudinal direction of the heat pipe and the other part is one end portion and the other end portion in the longitudinal direction of the heat pipe.

19. The heat sink according to claim 5, wherein the predetermined part is a central part in the longitudinal direction of the heat pipe and the other part is one end portion and the other end portion in the longitudinal direction of the heat pipe.

20. The heat sink according to claim 6, wherein the predetermined part is a central part in the longitudinal direction of the heat pipe and the other part is one end portion and the other end portion in the longitudinal direction of the heat pipe.
